(19) United States
(12) Patent Application Publication
(10) Pub. No.: US 2024/0201236 A1
(43) Pub. Date: Jun. 20, 2024

(54) Method and System for Supervising Electrical Consumption

(71) Applicant: SAGEMCOM ENERGY & TELECOM SAS, Bois-Colombes (FR)

(72) Inventors: Oussama Abid, Bois-Colombes (FR); Abbas Sabraoui, Bois-Colombes (FR); Ahmet Samed Basturk, Bois-Colombes (FR)

(21) Appl. No.: 18/541,366

(22) Filed: Dec. 15, 2023

(30) Foreign Application Priority Data
Dec. 16, 2022 (FR) 2213587

(51) Int. Cl. G01R 22/10; G01F 13/00; G01R 22/06

(52) U.S. Cl. CPC G01R 22/10; G01R 22/068; G01F 13/006

(57) ABSTRACT

The present disclosure relates to a method for supervising the electrical consumption of a battery-powered smart meter, including a measurement relating to the electrical current consumed by said meter,
characterized in that it includes:
an identification of at least one functionality implemented by the meter by comparison of data relating to this measurement that are measured with signatures stored in a signature database, each signature of said base being representative the consumption of the meter during the implementation of a functionality by said meter in a nominal operating mode of the meter;
a monitoring over time of the sequence of functionalities thus identified and the detection of a possible drift compared to a nominal operation.

### TECHNICAL FIELD

The present disclosure relates to a method and a system for supervising an electrical consumption of a battery-powered smart meter. More specifically, it finds application in the field of fluid meters (water meters, gas meters, etc.).

### BACKGROUND

Smart meters make it possible to monitor consumption data (water, gas, etc.) over time and to transmit these data, possibly in real time, to a manager of the remote distribution network. Different functionalities are managed by the microprocessor(s) of the meter (measurement, transmission and receipt of data, calculations, display, etc.). All the functionalities of the meter generate electrical consumption, as well as an associated current intensity value, which can vary over time. In a battery-powered smart system, with a service life that can extend over several years, electrical consumption anomalies (overconsumptions or underconsumptions) can appear and have multiple causes, such as changes in the conditions of the environment of the meter (temperature, humidity, etc.); anomalies in the application software of the meter, which may be difficult to detect; or premature wear of one or several electronic components of the meter.

These electrical consumption anomalies may have consequences on the service life of the battery. It is therefore desirable to be able to monitor the electrical consumption of the meter and to detect and alert of any operation drift or inconsistency compared to a nominal mode.

More generally, it is desirable to be able to monitor the proper operation of the embedded software throughout the service life of the meter.

### SUMMARY

A general aim is to propose a solution for overcoming the drawbacks of the smart meters of the state of the art.

To this end, a method for supervising the electrical consumption of a battery-powered smart meter is provided, comprising a measurement relating to the electrical current consumed by said meter,

The method comprising:
an identification of at least one functionality implemented by the meter by comparison of data relating to this measurement that are measured with signatures stored in a signature database, each signature of said base being representative of the consumption of the meter during the implementation of a functionality by said meter in a nominal operating mode of the meter;
a monitoring over time of the sequence of functionalities thus identified and the detection of a possible drift relative to a nominal operation,
an identification of at least one functionality implemented by the meter responsible for the drift.

Thus, the supervision method proposed makes it possible to identify sources responsible for the electrical consumption anomaly of the smart meter observed in relation to a normal operating mode, comprising functionalities of the meter.

The method also makes it possible to supervise, continuously or intermittently, the electrical current consumed by the different microcontrollers, radio modules and other elements that make up the constrained system.

The method also makes it possible to identify and monitor the actions taken by the embedded software of the meter.

The method also allows making an estimation of a remaining service life of the battery following an observed anomaly in the electrical consumption of the meter.

Finally, the method makes it possible to alert a user of any abnormal consumption detected by a supervision system.

According to one implementation of the method, the detection of a drift generates the emission of an alert signal and/or corrective actions.

According to one implementation of the method, a corrective action comprises a stopping of the functionality/functionalities or a reduction in a maximum current intensity allocated to this/these functionality/functionalities.

According to one implementation of the method, at least one given functionality is kept including in case of drift, so as to guarantee that the meter is kept in operation.

According to one implementation of the method, further comprising an estimation of a remaining service life of the battery based on the measured data.

According to one implementation of the method, the functionalities of the smart meter comprising one or several functionalities chosen among:
radio transmissions
operations performed by a microcontroller
metrology operations
low-consumption Bluetooth transmissions.

According to one implementation of the method, the method further comprises a detection of electrical overconsumption and/or electrical underconsumption by the smart meter.

The present disclosure further relates to a computer program product implementing the supervision method as described.

The present disclosure further relates to a system for supervising the electrical consumption of a smart meter, the supervision system operating thanks to application software distinct from application software of the meter, the supervision system comprising a microprocessor adapted to implement the proposed method.

Finally, the present disclosure relates to a battery-powered smart meter, comprising a supervision system as described.

### BRIEF DESCRIPTION OF THE DRAWINGS

One embodiment will now be presented by way of non-limiting example in support of the drawings in which:

FIG. 1 schematically illustrates a smart meter, comprising a supervision system as proposed.

FIG. 2 illustrates several signatures that can be comprised in the database.

FIG. 3 is a functional diagram of the supervision method as proposed, in its most general implementation.

FIG. 4 is a functional diagram illustrating the detection of signatures within the framework of the proposed method.

FIG. 5 is a functional diagram illustrating one particular implementation of the supervision method.

FIG. 6 is a block diagram illustrating a dynamic method for establishing a signature database.

### DETAILED DESCRIPTION

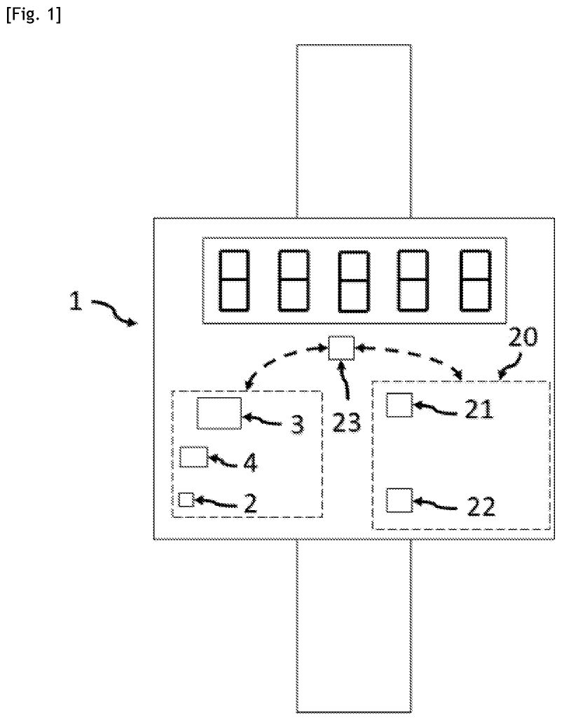

FIG. 1 represents a smart meter 1. Such a meter typically comprises a microprocessor 2, a battery 3 and communication means 4 with a remote server. It can in particular be a water or gas meter. This meter 1 is associated with a plurality of functionalities that together generate an overall electrical consumption of the meter. For example, for an electric meter, the functionalities can be emitting a radio signal, performing measurements or operating a microcontroller.

The method can be in particular implemented by a supervision system 20 of the meter 1, whose application system is distinct from an application system of the meter 1.

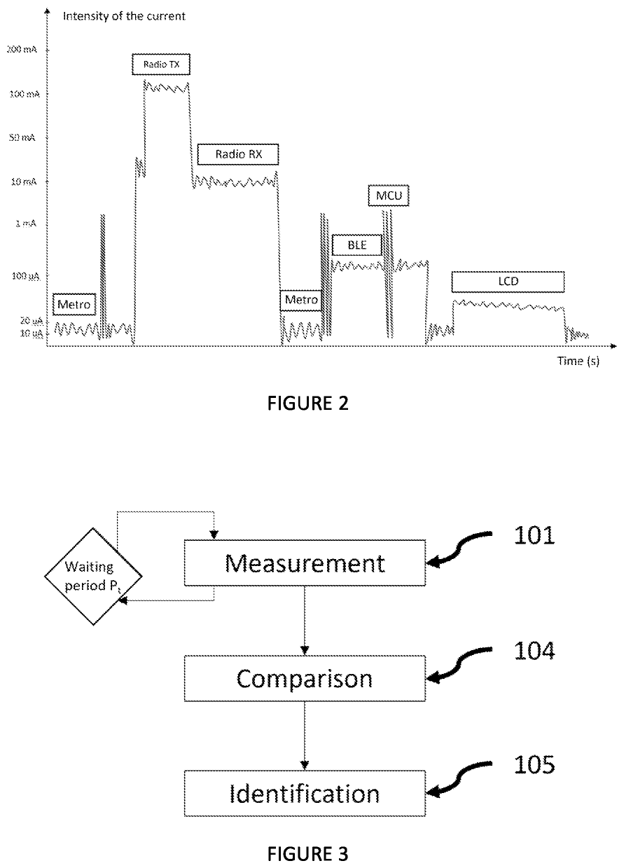

When each functionality is in normal operating mode, it consumes a certain value of current intensity which can be characterized by a signature, generally by a maximum value and an average value, and possibly a minimum value. The signature can also comprise other data, such as the frequency or duration of the signal: for example, and with reference to FIG. 2, a radio transmission is identifiable by an intensity of around ten milliamps over a period ranging from ten milliseconds to about ten seconds, while measurements are identifiable by short but regular current peaks. A drift in the consumed current intensity value, that is to say a current overconsumption or underconsumption compared to the expected nominal value, generally indicates that a functionality is not in its normal operating mode. This could for example be an anomaly in the software controlling the functionality, an overheating, or wear of some electronic components included in the functionality. Any consumption whose signature is not recognized and which adds a constant level of intensity over long periods is assimilated to a problem impacting the battery 3 of the smart meter 1.

The proposed method is implemented through the use of a database in order to identify one or several functionalities among the functionalities of the meter 1 which are responsible for such a current anomaly. In its most general implementation, and with reference to FIG. 3, the method comprises a first step 101 of measuring data relating to the electrical consumption of the meter 1. These data will generally comprise the current intensity value consumed by the meter, but could comprise other related values, such as the energy or the power consumed by a functionality, or the intensity variation between two instants. An initial instant t₀ and final instant tᵣ of the measurement 101, and a measurement step Δt between two successive measurement instants can thus be defined. The method then comprises a step 104 of comparing the measured data with signatures comprised in the database, which then allows a step 105 of identifying one or several signatures corresponding to functionalities responsible for the anomaly of the current.

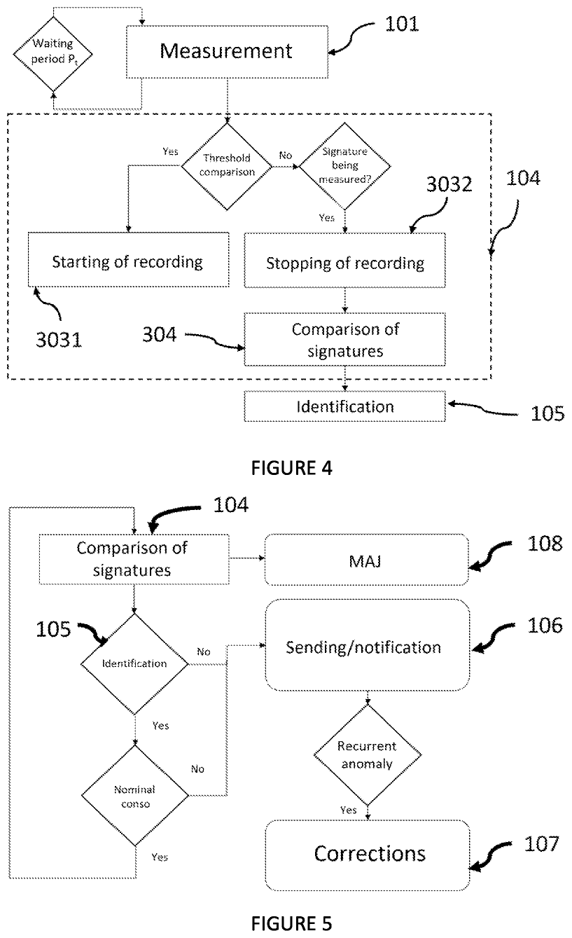

FIG. 4 illustrates signature detection sub-steps of the comparison step 104 according to the proposed method. A maximum threshold Sₘₐₓ is first defined. Step 101 of measuring data relating to the current, in particular intensity measurements carried out at a plurality of instants, is followed at each instant by a step 302 of comparing between each measured intensity value and this threshold. The threshold Sₘₐₓ is chosen to be indicative of a current overconsumption when the overall consumption of the meter 1 exceeds this threshold. As soon as a measured intensity value exceeds the threshold Sₘₐₓ, a recording 303 is initiated in step 3031 to record, for example in a memory of the supervision system 20, some data chosen among the measured data. It can be chosen to record all the data measured during the measurement step 301, or only some of these data considered to be more important, so as not to overload the memory of the supervision system 20. Advantageously, the recording 303 will comprise the recording of a maximum level of consumed intensity Iₘₐₓ, of an average level of consumed intensity I_{avg} and of a minimum level of consumed intensity Iₘᵢₙ over the total recording duration. The recording thus obtained can then be the subject of a comparison 304 with the signatures contained in the database. The comparison 304 can possibly be followed by a notification of the results of the comparison 304 to the controller 23 of the supervision system 20. The identification 105 of the functionalities 5 responsible for the electrical consumption anomaly of the smart meter 1 will then be carried out.

The recording is ended in a step 3032 as soon as a measured intensity value is lower than the threshold Sₘₐₓ, which indicates a return to a normal operating mode.

Optionally, the method can initiate the recording only when a plurality of measured intensity values exceed the threshold Sₘₐₓ, and/or stop the recording 303 only when a plurality of measured intensity values is found below the maximum threshold Sₘₐₓ. By a plurality of values it is meant either a predetermined number of measured values, or several values measured during a predetermined period of time. This avoids inadvertent launching and/or stopping of the recording 303 due to aberrant measured values, not representative of the signal sought to be identified.

It is also possible, in an analogous manner, to define a minimum threshold Sₘᵢₙ indicative of an overall current under-consumption of the meter 1, either instead of the maximum threshold Sₘₐₓ, or in a manner complementary thereto.

According to one particular implementation, it is also possible to define a noise threshold S_{b}, corresponding to a current intensity value below which a measured value is not considered by the method as being indicative of a physical phenomenon. In other words, the method will not provide any action based on this measured value, even if it is lower than the minimum threshold Sₘᵢₙ defined previously. This makes it possible to exclude the measurements which correspond to a background noise and not to an actual physical signal due to a functionality 5 of the smart meter 1.

For the sub-steps of the comparison 104, the supervision system 20 defines a sliding window, whose size and resolution will depend on the characteristics of the system, in particular its calculation capacity, its memory capacity RAM, and/or the maximum size of the signatures it may contain. For example, the table 1 illustrates the identification of an intensity level signature used by the meter, performed at a plurality of instants. The threshold Sₘₐₓ is set at 12 microamps, so that a signature is identified between the instants t₋₁₅ and t₋₇.

| | | | | | | | | | | | | | | | | | |
|---|---|---|---|---|---|---|---|---|---|---|---|---|---|---|---|---|---|
| Instant | t₋ₙ | . . . | . . . | t₋₁₅ | t₋₁₄ | t₋₁₃ | t₋₁₂ | t₋₁₁ | t₋₁₀ | t₋₉ | t₋₈ | t₋₇ | t₋₆ | t₋₄ | t₋₂ | t₋₁ | t₋₀ |

| | | | | | | | | | | | | | | | |
|---|---|---|---|---|---|---|---|---|---|---|---|---|---|---|---|
| Measured | 10 | 12 | 16 | 1580 | 1202 | 1603 | 1258 | 48 | 16 | 12 | 10 | 10 | 11 | 12 | 10 |
| intensity | | | | | | | | | | | | | | | |
| (μA) | | | | | | | | | | | | | | | |

The functionalities of the smart meter 1 can comprise, for example but without limitation, radio transmissions, operations performed by one or several microcontrollers, metrology operations and/or Bluetooth low-energy transmissions (or BLE).

The method can further comprise a detection of a drift in the measured data relative to an expected nominal operation of the meter.

According to one embodiment, the meter 1 comprises an interface 23 between the supervision system 20 and the rest of the meter 1, intended to exchange data therebetween. When the comparison 104 has enabled the identification 105 of one or several signatures of functionalities of the meter 1 in the consumed intensity value, the recorded data can thus be sent during a sending step 106 to the supervision system 20 so as to allow their post-processing. When no identification 105 of signatures of functionalities of the meter 1 comprised in the database is obtained, the sending step 106 will be accompanied by a notification, so as to alert the supervision system 20 that an anomaly is taking place in the electrical consumption of the meter 1. Optionally, it can be provided that the sending step 106 comprises the sending of a notification when one or several signatures are identified but when the consumption is not nominal compared to the values recorded in the database, and in particular when under-consumption or over-consumption takes place. For example, the database can comprise signatures indicating a consumed nominal intensity as well as a range of values of intensities corresponding to the signature. If the recorded data comprise intensity values that diverge from the nominal intensity but are within the range of values thus defined, then the signature is identified but is considered non-nominal, and the sending step 106 then comprises a notification to the supervision system 20. A non-nominal signal but corresponding to a known signature will therefore typically have a period comparable to that of the corresponding nominal signal, with a change in the average intensity. Thus, any observation of a drift in the measured data compared to the expected nominal operation of the meter is notified to the supervision system, in order to alert it.

FIG. 5 illustrates one particular implementation of the proposed supervision method. This implementation comprises the implementation of corrections 107 aimed at restoring a normal operation of the meter 1, in particular to moderate the reduction of the remaining service life of the battery during current overconsumption. Such corrections 107 can comprise a restriction of the functionalities identified as responsible for a current anomaly, in particular an exceeded threshold. It may be advantageous to implement these restrictions only when an anomaly is observed recurrently, as established following the observation, in the comparison step 104, of a drift in the consumption compared to a nominal consumption and in the step 106 of sending data to the supervision system 20 via the interface 23. According to predefined criteria, such as a remaining capacity of the energy source of the meter 1, or the essential nature of the functionalities responsible for the current anomaly, the restriction 107 can consist of the total stopping of the responsible functionalities, or in a more moderate manner of a restriction of the current intensity that they can receive from the energy source for their operation. Additionally or alternatively, some functionalities could be defined as essential functionalities, for which it is necessary to allocate a certain current intensity value. If some of these essential functionalities form part of the functionalities responsible for a current anomaly, the restriction 107 could reduce the current allocated to these essential functionalities, but only so as to allow them to operate satisfactorily. On the other hand, if some of the functionalities responsible for an anomaly do not form part of the essential functions, the current allocated to them can be reduced further, because deterioration of their operation or the total shutdown of the current is considered as admissible. In case of overconsumption, the current can thus be managed in order to prioritize the functionalities considered as essential.

The corrections 107 can be implemented by a modification, possibly automated modification, of the configuration of application software of the smart meter 1.

The supervision method can further comprise a calculation 108 of the remaining energy level C_{remaining} in the battery 3 of the meter 1 following the detection of a current anomaly. This energy level is calculated according to the equation:

$${C}_{remaining ( t )} = {C}_{remaining ( t - 1 )} - ( {Δ}_{t} * {I}_{i d l e} ) - ( {Δ}_{s i g} * {I}_{s i g} )$$

Where Δt is the step between two detected signatures, Δsig the duration of the detected signature, I_{idle} the average nominal consumption of the meter 1 and I_{sig} the average intensity of the detected signature, and t and t−1 respectively represent instants after and before the current anomaly. This calculation of the remaining energy level will possibly allow estimating a remaining service life of the battery 3.

The present disclosure also concerns a computer program product implementing the supervision method described above.

As mentioned previously, the smart meter 1 as described includes a supervision system 20 making it possible to implement the proposed method. This system 20 operates using application software distinct from that of the meter 1. It comprises at least one microprocessor 22, which may be distinct from a microprocessor of the meter 1, or operate using the same multi-core processor as the meter 1 by using a core distinct from the one used by the meter 1. Alternatively, the meter 1 and the supervision system 20 can operate using the same microprocessor 22 implementing two distinct application softwares. The supervision system 2 comprises at least one detection element 21 capable of detecting the current flow. This can in particular be a resistance of low value, of the order of a milliohm, placed in the current path. The current value is deduced from the voltage across the meter 1 using Ohm's law.

The fact of providing a supervision system 20 operating using application software different from application software of the meter 1 makes it possible to avoid the transmission of a bug appearing in one of these two softwares to the second.

The database comprising the signatures used by the proposed supervision method can be established by a static method or a dynamic method. Table 2 illustrates examples of functionalities, with the associated minimum, average and maximum intensity, the duration of the signal and the period, where appropriate.

| | Intensity | | | | | | | | Period |
|---|---|---|---|---|---|---|---|---|---|
| Functionality | Minimum | | Average | | Maximum | | Duration | | (if synchronization) |
| Metrology | 2 | μA | 5 | μA | 10 | μA | 10 | ms | 125 ms |
| Radio | 10 | mA | 60 | mA | 120 | mA | 200 | ms | 1 per day |
| Button | 1 | mA | 1.2 | mA | 1.6 | mA | 200 | ms | — |
| LCD | 235 | μA | 250 | μA | 255 | μA | 60 | sec | — |
| BLE | 5 | mA | 6 | mA | 7 | mA | 20 | sec | — |
| External | 1.5 | mA | 1.6 | mA | 1.7 | mA | 20 | sec | 1 per day |
| flash | | | | | | | | | |

The static method consists of injecting a reference database 10 into the embedded software of the meter 1, this base being established prior to the assembly of the meter, for example by laboratory measurements.

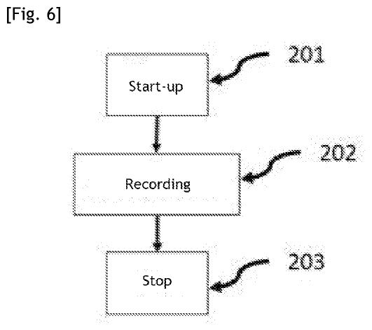

Referring to FIG. 6, the dynamic method consists of establishing the database during the operation of the meter. This dynamic method must be done in the nominal operating mode of the meter, that is to say when it is established that no anomaly in the consumed current is taking place. A functionality of the meter whose signature is to be obtained is started according to a step 201. Then, a recording 202 of data relating to the electrical current consumed by the functionality is initiated, which data will determine its signature—for example but in a non-limiting manner, a minimum Iₘᵢₙ, maximum Iₘₐₓ, and/or average I_{avg} intensity value, a signal duration or a frequency. When the signature is obtained, the recording is ended and the functionality is stopped in a stopping step 203. This dynamic method has the advantage of allowing the addition of functionalities subsequently to the manufacture of the meter 1, then the characterization of their signatures in order to be able to implement the proposed supervision method. This dynamic method can also be implemented for a given duration for a plurality of functionalities in order to establish a database for all these functionalities.

When supervision of the meter 1 is desired at any time of its operation, the supervision system 20 can implement the proposed method continuously. Alternatively, and in order to avoid the production of overconsumption by the supervision system 20 itself, it is possible to implement the method intermittently. A first alternative is to perform measurements for a given period over a time range, for example but without limitation for ten seconds every hour. A second alternative is to modulate the measurement step Δt. These two alternatives can possibly be combined by sampling a given number of measurements during a given period over a time range. Another alternative, which can be performed separately or in combination with the previous ones, is to synchronize the implementation of the supervision method with an event which is known to have an influence on the overall consumption of the meter 1, such as the start of a radio signal emission.

An intermittent operation of the supervision system 20 can make it possible to detect certain current anomalies, such as sporadic consumption drifts, or periodic overconsumptions, while extending the service life of the energy source compared to a continuous supervision.

According to one particular implementation, when it is desired to further limit the loss of service life of the energy source associated with the use of the supervision system 20, it is possible to assign a percentage of the capacity of the energy source, or a maximum current intensity to the supervision system 20. It is for example possible, but without limitation, to allocate 5% of the total capacity of the battery 3 to the operation of the supervision system 20, and thus ensure that no consumption drift or anomaly goes unnoticed.

Typically, the dimensioning of the supervision system 20 is performed during the manufacture of the meter, so as to meet such a consumption limit as to the capacity of the battery. For example, but without limitation, it is possible to allocate a current of one hundred microamps for a supervision system 20 operating continuously, or of twenty microamps per measurement for a supervision system performing discrete measurements.

1. A method for supervising the electrical consumption of a battery-powered smart meter, comprising a measurement relating to the electrical current consumed by said meter,
characterized in that it comprises:
an identification of at least one functionality implemented by the meter by comparison of data relating to this measurement that are measured with signatures stored in a signature database, each signature of said database being representative of the consumption of the meter during the implementation of a functionality by said meter in a nominal operating mode of the meter;
a monitoring over time of the sequence of functionalities thus identified and the detection of a possible drift relative to a nominal operation,
an identification of at least one functionality implemented by the meter responsible for the drift.

2. The method according to claim 1, wherein the detection of a drift generates the emission of an alert signal and/or corrective actions.

3. The method according to claim 2, wherein a corrective action comprises a stopping of the functionality/functionalities responsible for the drift or a reduction in a maximum current intensity allocated to this/these functionality/functionalities.

4. The method according to claim 1, wherein at least one given functionality is kept including in case of drift, so as to guarantee that the meter is kept in operation.

5. The method according to claim 1, further comprising an estimation of a remaining service life of the battery based on the measured data.

6. The method according to claim 1, the functionalities of the smart meter comprising one or several functionalities chosen among:
radio transmissions
operations performed by a microcontroller
metrology operations
low-consumption Bluetooth transmissions.

7. The method according to claim 1, further comprising a detection of electrical overconsumption and/or electrical underconsumption by the smart meter.

8. A computer program product implementing the supervision method according to claim 1.

9. A system for supervising the electrical consumption of a smart meter, the supervision system operating thanks to application software distinct from application software of the meter, the supervision system comprising a microprocessor adapted to implement the method according to claim 1.

10. A battery-powered smart meter, comprising a supervision system according to the preceding claim.
